(19) United States
(12) Patent Application Publication
(10) Pub. No.: US 2026/0247799 A1
(43) Pub. Date: Aug. 20, 2026

(54) Display Substrate and Preparation Method Thereof, and Display Apparatus

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Dongdong SU, Beijing (CN); Yinhu HUANG, Beijing (CN); Yuhao LEE, Beijing (CN); Bingming FENG, Beijing (CN); Xiaobin SHEN, Beijing (CN); Cao WU, Beijing (CN); Huanhuan WANG, Beijing (CN); Lingang WEN, Beijing (CN); Fushuang ZHANG, Beijing (CN); Jianming ZOU, Beijing (CN); Ruquan LI, Beijing (CN); Jixing WANG, Beijing (CN); Junkai YAN, Beijing (CN); Xiaoyin YANG, Beijing (CN); Xiong YANG, Beijing (CN); Xueliang ZHU, Beijing (CN); Dacheng ZHANG, Beijing (CN)

(21) Appl. No.: 18/839,032

(22) PCT Filed: Sep. 26, 2023
(86) PCT No.: PCT/CN2023/121706

§ 371 Date: Aug. 16, 2024

(51) Int. Cl. H10K 59/122; H10K 59/12

(52) U.S. Cl. CPC H10K 59/122; H10K 59/1201

(57) ABSTRACT

A display substrate and a-preparation method thereof, and a display apparatus. The display substrate includes: a base substrate, and a first electrode and a pixel definition layer The pixel definition layer is provided with a pixel opening exposing the first electrode. A region where the first electrode is located includes: a first electrode region, a second electrode region, and a smooth transition region located between first electrode region and second electrode region. An orthographic projection of a first electrode in the first electrode region on the base substrate coincides with that of the pixel opening on the base substrate. An orthographic projection of a first electrode in the second electrode on the base substrate overlaps with that of the pixel definition layer on the base substrate. A thickness of the first electrode in the first electrode region is smaller than that of the first electrode in the second electrode region.

### CROSS-REFERENCE TO RELATED APPLICATION

The present application is a U.S. National Phase Entry of International Application No. PCT/CN2023/121706 having an international filing date of Sep. 26, 2023, the content of which is hereby incorporated by reference.

### TECHNICAL FIELD

The present disclosure relates to, but is not limited to the technical field of display, in particular relates to a display substrate, a preparation method thereof, and a display apparatus.

### BACKGROUND

Micro organic light-emitting diode (Micro-OLED for short) is a micro display developed in recent years, and silicon-based OLED is a kind of micro display. Silicon-based OLEDs are manufactured using the mature Complementary Metal Oxide Semiconductor (CMOS) integrated circuit process. Due to their advantages such as small size, high Pixels Per Inch (PPI), and high refresh rate, they are widely used in the near-to-eye display field of Virtual Reality (VR) or Augmented Reality (AR).

### SUMMARY

The following is a summary of subject matter described in the present disclosure in detail. This summary is not intended to limit the protection scope of claims.

In a first aspect, an embodiment of the present disclosure provides a display substrate, including: a base substrate, and a first electrode and a pixel definition layer sequentially arranged on the base substrate. The pixel definition layer is provided with a pixel opening exposing the first electrode; and a region in which the first electrode is located includes: a first electrode region, a second electrode region and a smooth transition region. The smooth transition region is located between the first electrode region and the second electrode region, an orthographic projection of a first electrode located in the first electrode region on the base substrate coincides with an orthographic projection of the pixel opening on the base substrate, and an orthographic projection of a first electrode located in the second electrode region on the base substrate partially overlaps with an orthographic projection of the pixel definition layer on the base substrate.

A thickness of the first electrode located in the first electrode region is smaller than a thickness of the first electrode located in the second electrode region.

In some possible implementations, an orthographic projection of an edge of a top layer of the pixel definition layer on the base substrate is located within an orthographic projection of the smooth transition region on the base substrate.

In some possible implementations, the first electrode includes: a first structure and a second structure, wherein the first structure is located on a side of the second structure away from the base substrate.

An orthographic projection of the first structure on the base substrate covers an orthographic projection of the second structure on the base substrate, and a thickness of the second structure is greater than a thickness of the first structure.

The first structure covers a side wall of the second structure.

In some possible implementations, a surface of the second structure close to the pixel definition layer is flat; a first thickness is a thickness of a first structure located in the first electrode region, and a second thickness is a thickness of a first structure located in the second electrode region, and the first thickness is less than the second thickness.

In some possible implementations, a ratio of the second thickness to the first thickness ranges from 1.3/1 to 4/1.

In some possible implementations, a third thickness is a thickness of a pixel definition layer, wherein an orthographic projection of the pixel definition layer on the substrate overlaps with an orthographic projection of a surface of the second structure close to the pixel definition layer on the base substrate; a ratio of the third thickness to a thickness difference is in the range of 10:1 to 20:1, wherein the thickness difference is a difference between the second thickness and the first thickness.

In some possible implementations, the first structure is a transparent electrode structure, and a thickness of the first structure is greater than 80 angstroms.

In some possible implementations, the second structure includes: a first sublayer, a second sublayer, a third sublayer, and a fourth sublayer sequentially stacked on the base substrate; wherein a thickness of the third sublayer is greater than a thickness of any one of the first sublayer, the second sublayer, and the fourth sublayer.

An orthographic projection of a surface of the first sublayer away from the base substrate on the base substrate covers an orthographic projection of the second sublayer on the base substrate, and an orthographic projection of a surface of the second sublayer away from the base substrate on the base substrate covers an orthographic projection of the third sublayer on the base substrate, and an orthographic projection of a surface of the third sublayer away from the base substrate on the base substrate covers an orthographic projection of the fourth sublayer on the base substrate.

A side wall of the second structure is inclined.

In some possible implementations, a conductivity of the third sublayer is greater than a conductivity of any one of the first sublayer, the second sublayer, and the fourth sublayer.

In some possible implementations, a preparation material of the first sublayer includes titanium, a preparation material of the second sublayer includes titanium nitride, a preparation material of the third sublayer includes aluminum, and a preparation material of the fourth sublayer includes titanium nitride.

In some possible implementations, the pixel definition layer includes: a first inorganic layer, a second inorganic layer, a third inorganic layer, and a fourth inorganic layer sequentially stacked on the base substrate.

A surface of the first inorganic layer away from the base substrate is flat, and a distance between the surface of the first inorganic layer away from the base substrate and the base substrate is equal to a distance between a surface of a first structure located in the second electrode region and located on the second structure and the base substrate.

In some possible implementations, an orthographic projection of a surface of the first inorganic layer close to the base substrate on the base substrate at least partially overlaps with an orthographic projection of a surface of the first structure on the base substrate on the base substrate.

In some possible implementations, an orthogonal projection of the second inorganic layer on the base substrate covers an orthogonal projection of the first inorganic layer on the base substrate, the second inorganic layer is provided with a first via, and the first via exposes the first electrode located in the first electrode region.

In some possible implementations, an orthographic projection of the third inorganic layer on the base substrate at least partially overlaps with an orthographic projection of any one of the first inorganic layer and the second inorganic layer on the base substrate.

The third inorganic layer is provided with a second via and a third via, wherein the second via exposes the first electrode located in the first electrode region, and the third via exposes the second inorganic layer.

An orthographic projection of the first via on the base substrate coincides with an orthographic projection of the second via on the base substrate.

In some possible implementations, an orthographic projection of the fourth inorganic layer on the base substrate at least partially overlaps with an orthographic projection of any one of the first inorganic layer and the third inorganic layer on the base substrate.

The fourth inorganic layer is provided with a fourth via and a fifth via, wherein the fourth via exposes the first electrode located in the first electrode region, and the fifth via exposes the second inorganic layer.

An orthogonal projection of the fourth via on the base substrate coincides with the orthogonal projection of the second via on the base substrate, and an orthogonal projection of the fifth via on the base substrate partially overlaps with an orthogonal projection of the third via on the base substrate.

In some possible implementations, the third via and the fourth via constitute a groove formed on the pixel definition layer, and the groove is an undercut structure.

In some possible implementations, a thickness of the first inorganic layer is greater than a thickness of any one of the second inorganic layer, the third inorganic layer, and the fourth inorganic layer, and the thickness of the third inorganic layer is greater than the thickness of any one of the second inorganic layer and the fourth inorganic layer. An etching rate of the third inorganic layer is greater than an etching rate of the fourth inorganic layer.

In some possible implementations, a preparation material of the first inorganic layer includes silicon oxide, a preparation material of the second inorganic layer includes silicon oxide, a preparation material of the third inorganic layer includes silicon nitride, and a preparation material of the fourth inorganic layer includes silicon oxide.

In some possible implementations, the display substrate further includes: an organic light emitting layer, a second electrode, an encapsulation layer, a filter layer, and an optical device layer sequentially stacked on the pixel definition layer. Herein, the filter layer includes a plurality of filters. The optical device layer includes a plurality of optical devices.

Orthographic projections of adjacent filters on the base substrate are at least partially overlapped, and the plurality of filters correspond in a one-to-one mode with the plurality of optical devices.

An orthographic projection of a filter on the substrate partially overlaps with an orthographic projection of a corresponding optical device on the substrate; and there are intervals between adjacent optical devices.

In a second aspect, embodiments of the present disclosure provide a display apparatus, including the display substrate described in any embodiment of the first aspect.

In a third aspect, embodiments of the present disclosure provide a preparation method for a display substrate, configured to prepare the display substrate as described in any embodiment of the first aspect. The method includes: forming a first electrode on a base substrate; and forming a pixel definition layer on the first electrode.

In some possible implementations, forming the first electrode on the base substrate includes: depositing a first metal film, a second metal film, a third metal film, and a fourth metal film on the base substrate, patterning the first metal film, the second metal film, the third metal film, and the fourth metal film by a patterning process to form a second structure; depositing a transparent metal thin film on the second structure, patterning the transparent metal thin film by a patterning process to form a first structure, and forming the first electrode including the first structure and the second structure.

In some possible implementations, forming the pixel definition layer on the first electrode includes: depositing a first inorganic thin film on the first electrode, forming a first inorganic layer by two patterning processes; depositing a second inorganic thin film, a third inorganic thin film, and a fourth inorganic thin film on the first inorganic layer; patterning the second inorganic thin film, the third inorganic thin film, and the fourth inorganic thin film by a patterning process to form a second inorganic layer, a third inorganic layer, and a fourth inorganic layer; and forming the pixel definition layer including the first inorganic layer, the second inorganic layer, the third inorganic layer, and the fourth inorganic layer; a selection ratio for etching the second inorganic thin film to the transparent metal thin film ranges from 20:1 to 40:1; a selection ratio for etching the fourth inorganic thin film to the third inorganic thin film ranges from 1:6 to 1:9.

Other aspects may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a display substrate according to an exemplary embodiment of the present disclosure.

FIG. 2 is a schematic diagram of differences among a first thickness, a second thickness, and a third thickness provided by an exemplary embodiment of the present disclosure.

FIG. 3 is a schematic diagram of a Transmission Electron Microscope (TEM) slice of FIG. 2.

FIG. 4 is a schematic diagram of mapping of thickness and reflectivity of a first structure according to an exemplary embodiment of the present disclosure.

FIG. 5 is a structural schematic diagram of a second structure according to an embodiment of the present disclosure.

FIG. 6 is a schematic diagram of a structure of a base substrate according to an embodiment of the present disclosure.

FIG. 7 is a schematic diagram of a circuit principle according to an exemplary implementation.

FIG. 8 is a schematic diagram of an implementation of a circuit of a voltage control circuit and a pixel driving circuit.

FIG. 9 is a schematic diagram of a structure of a display substrate according to another exemplary embodiment of the present disclosure.

FIG. 10 is a schematic diagram of a structure of an organic light emitting layer according to an embodiment of the present disclosure.

FIG. 11A is a first schematic diagram of a display substrate according to an embodiment of the present disclosure.

FIG. 11B is a second schematic diagram of an organic light-emitting diode display substrate according to an embodiment of the present disclosure.

FIG. 11C is a third schematic diagram of an organic light-emitting diode display substrate according to an embodiment of the present disclosure.

FIG. 11D is a fourth schematic diagram of an organic light-emitting diode display substrate according to an embodiment of the present disclosure.

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings of the embodiments of the present disclosure only involve structures involved in the embodiments of the present disclosure, and for other structures, reference may be made to conventional designs.

In the accompanying drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction with which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is- 5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulating film” may be replaced with an “insulating layer” sometimes.

In the specification, “arranged in a same layer” refers to a structure formed by patterning two (or more than two) structures through a same patterning process, and their materials may be the same or different. For example, materials of precursors for forming multiple structures arranged in a same layer are the same, and final materials may be the same or different.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

An OLED display substrate includes: a silicon-based backplane integrated with a driving circuit, and a pixel definition layer and an OLED light-emitting element array formed on the silicon-based backplane. Herein, the OLED light-emitting element array includes an anode, an organic light emitting layer and a cathode. A transition of the anode edge protrusion is not smooth, which makes the light emitted by the display substrate uneven, and reduces the display effect of the display substrate.

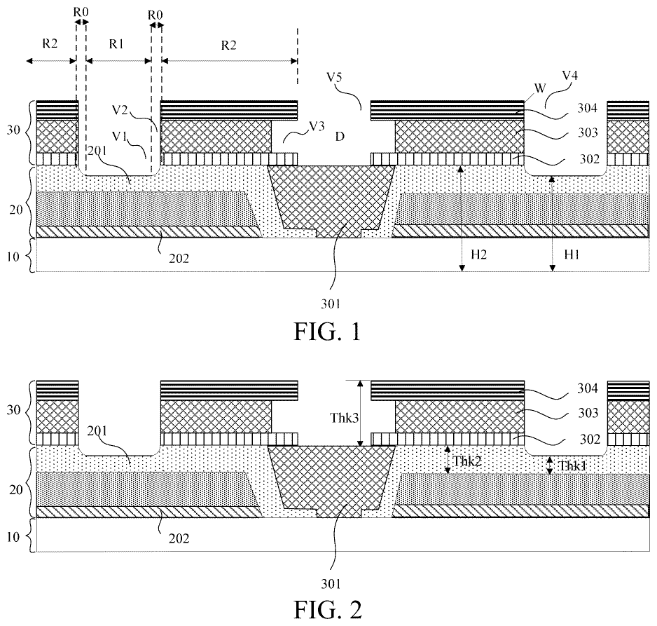

FIG. 1 is a schematic diagram of a structure of a display substrate according to an example embodiment of the present disclosure. As shown in FIG. 1, the display substrate includes: a base substrate 10, a first electrode 20 and a pixel definition layer (PDL) 30 sequentially disposed on the base substrate 10. Herein the pixel definition layer is provided with a pixel opening exposing the first electrode, and a region in which the first electrode located includes: a first electrode region R1, a second electrode region R2 and a smooth transition region RO. The smooth transition region RO is located between the first electrode region R1 and the second electrode region R2. An orthographic projection of a first electrode 20 located in the first electrode region R1 on the base substrate 10 coincides with an orthographic projection of the pixel opening on the base substrate 10, and an orthographic projection of a first electrode 20 located in the second electrode region R2 on the base substrate 10 overlaps with an orthographic projection of the pixel definition layer on the base substrate 10. A thickness H1 of the first electrode located in the first electrode region is smaller than a thickness H2 of the first electrode located in the second electrode region. Herein smooth transition means that the curvature does not have any abrupt change at the bottom edge.

In an exemplary implementation, as shown in FIG. 1, the region in which the first electrode 20 is located includes a first electrode region R1, two smooth transition regions RO, and two second electrode regions R2 in terms of structure.

There is a smooth transition region R0 in the first electrode region R1 and the second electrode region R2. The smooth transition region R0 can improve the uniformity of the light emitted by the OLED device, improve the display effect, and avoid the uneven light emitted caused by the unsmooth protrusion transition of the first electrode.

In an exemplary implementation, by controlling a difference between a thickness of the first electrode below the PDL non-opening and a thickness of the first electrode below the PDL opening, the thickness of the first electrode located in the first electrode region is smaller than the thickness of the first electrode located in the second electrode region, thereby achieving the purpose of alleviating light leakage at the PDL enclosed edge (non-opening) and improving light emitting efficiency at the PDL opening, and thereby improving the display effect of the display substrate. It can solve the problem that as Pixels Per Inch (PPI) gradually increases, a size between pixels under the same size decreases, and the edge of a single pixel is prone to light leakage and color impurity.

In an exemplary implementation, the base substrate 10 may be a driving backplane.

In an exemplary implementation, the display substrate may further include: an organic light emitting layer (EL) and a second electrode sequentially stacked on the pixel definition layer. The organic light emitting layer is located between the first electrode and the second electrode, and emits light under the joint action of the first electrode and the second electrode.

In an exemplary implementation, the first electrode may be an anode and the second electrode may be a cathode.

For the display substrate provided by embodiments of the present disclosure, a smooth transition region is arranged between the first electrode region and the second electrode region, which can improve the uniformity of light emitted by the OLED device, improve the display effect, and avoid the uneven light emitted caused by an unsmooth protrusion transition of the first electrode.

In an exemplary embodiment of the present disclosure, an orthographic projection of an edge W of the top layer of the pixel definition layer shown in FIG. 1 on the base substrate 10 is located within an orthographic projection of the transition region R0 on the base substrate 10.

In an exemplary implementation, a thickness of the first electrode located in the smooth transition region R0 increases sequentially in a direction from the second electrode region to the first electrode region.

In an exemplary embodiment of the present disclosure, the first electrode 20 may include: a first structure 201 and a second structure 202, wherein the first structure is located on a side of the second structure away from the base substrate.

An orthographic projection of the first structure on the base substrate covers an orthographic projection of the second structure on the base substrate, and a thickness of the second structure is greater than a thickness of the first structure; wherein the first structure covers the side wall of the second structure.

In an exemplary implementation, the second structure includes a metallic material.

In an exemplary implementation, as shown in FIG. 1, the orthographic projection of the first structure on the base substrate covers the orthographic projection of the second structure on the base substrate, i.e., a cross-sectional area of the first structure is greater than a cross-sectional area of the second structure, and the first structure can protect the metal in the second structure from corrosion.

In an exemplary implementation, as shown in FIG. 1, a thickness of the second structure may be greater than a thickness of the first structure in a direction perpendicular to the base substrate.

In an exemplary implementation, as shown in FIG. 1, an included angle between the side wall of the second structure and the base substrate is an acute angle, which, for example, may be greater than or equal to 50 degrees, and less than 90 degrees.

In an exemplary implementation, the first structure may be a transparent electrode structure, and the first structure may include indium tin oxide (ITO).

In an exemplary implementation, as shown in FIG. 1, a shape of a longitudinal section of the second structure may be rectangular or trapezoidal. FIG. 1 illustrates an example of a trapezoidal shape of the longitudinal section of the second structure.

In an exemplary implementation, as shown in FIG. 1, a side wall of the second structure may be inclined.

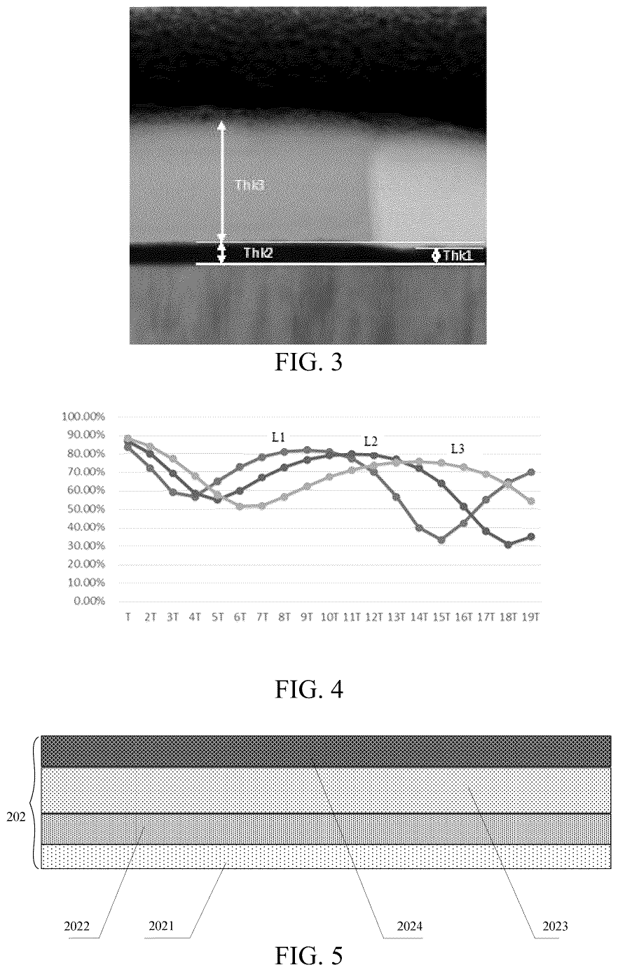

FIG. 2 is a schematic diagram of differences among a first thickness, a second thickness, and a third thickness provided by an exemplary embodiment of the present disclosure, and FIG. 3 is a schematic diagram of a transmission electron microscope (TEM) slice of FIG. 2. As shown in FIGS. 2 and 3, a surface of the second structure close to the pixel definition layer is flat; and the first thickness Thk1 may be a thickness of the first structure located in the first electrode region, and the second thickness Thk2 may be a thickness of the first structure located in the second electrode region, and the first thickness is less than the second thickness.

According to the embodiments of the present disclosure, the difference between the thickness of the first structure below the non-opening of the PDL and the thickness of the first structure below the opening of the PDL can be controlled, so that the thickness of the first structure below the non-opening of the PDL is smaller than the thickness of the first structure below the opening of the PDL, thereby alleviating light leakage at sides of a product, alleviating the expected light leakage characteristic, and improving color stability at low voltage.

In an exemplary embodiment of the present disclosure, a ratio of the second thickness Thk2 to the first thickness Thk1 is about 1.3/1 to 4/1.

FIG. 4 is a schematic diagram of mapping of thickness and reflectivity of a first structure according to an exemplary embodiment of the present disclosure. As shown in FIG. 4, the influence of the thickness of the first structure on the reflectivity fluctuates periodically, and the reflectivity decreases with the period. In FIG. 4, the abscissa indicates the time, the unit may be expressed by the period T, and the ordinate indicates the reflectivity. The thickness of the first structure corresponding to the line L1 is 460 microns (um), the thickness of the first structure corresponding to the line L2 is 525 um, and the thickness of the first structure corresponding to the line L3 is 610 um.

From the perspective of light emitting, in the first cycle of the film thickness, if the thickness of the first structure is relatively small, the transmittance of the first electrode will be increased.

From the perspective of light leakage, in the first cycle of the film thickness, if the thickness of the first structure is relatively large, the transmittance of the first electrode will be reduced, thereby alleviating light leakage at the PDL enclosed edge.

In exemplary implementations, the thickness of the first structure is greater than 80 angstroms, which can ensure that the first structure can protect the metal in the second structure from the effects of acids, bases and/or oxidation during subsequent processes.

From the perspective of structural stability, an increase in the thickness of the first structure will increase the protection for the second structure, thereby alleviating the risk of oxidation and corrosion of the metal film layer in the second structure, and improving the stability of the entire anode structure.

In an exemplary implementation, the display substrate in the present disclosure further includes an organic light emitting layer.

Based on the light emitting, light leakage and structural stability factors shown above, the ITO thickness Thk2 below the PDL non-opening (enclosed edge) and the ITO thickness Thk1 at the PDL opening can be differentiated. Thk2: Thk1=1.3:1 to 4:1, i.e., the thickness of the ITO below the PDL non-opening is 1.3 to 4 times the thickness of the ITO at the PDL opening, which can reduce the overall transmittance at the PDL non-opening, increase the overall transmittance at the PDL opening, and reduce the efficiency of the organic light emitting layer in the PDL enclosed region to about 80% of the original, increase the efficiency of the organic light emitting layer at the PDL opening to about 120% of the original, and reduce the light leakage at the PDL enclosed region to about 40% of the original.

In an exemplary embodiment of the present disclosure, as shown in FIGS. 2 and 3, a third thickness Thk3 is a thickness of the pixel definition layer of which an orthographic projection on the base substrate overlaps with an orthographic projection of a surface of the second structure close to the pixel definition layer on the base substrate. A ratio of the third thickness to a thickness difference is about 10:1 to 20:1, wherein the thickness difference is the difference between the second thickness and the first thickness. By controlling a ratio of the third thickness Thk3 and the difference |Thk2-Thk1| between the second thickness and the first thickness to maintain a certain thickness ratio in the present disclosure, it is ensured that the organic light emitting layer is stably in deformation at the PDL enclosed edge to control the internal electrical balance of the organic light emitting layer.

In an exemplary implementation, Thk3:|Thk2-THk1|=10:1~20:1, ensuring that the organic light emitting layer is stably in deformation at the PDL non-opening to control the internal electrical balance of the organic light emitting layer. Thk3:|Thk2-THk1|below 10:1, which causes an imbalance in the internal resistance distribution of the organic light emitting layer, can be avoided; and Thk3:|Thk2-THk1|more than 20:1, which causes severe distortion of the material of the organic light emitting layer at the PDL discontinuity resulting in misalignment of the material lamination in the organic light emitting layer, can be avoided.

FIG. 5 is a structural schematic diagram of a second structure provided by an embodiment of the present disclosure. As shown in FIG. 5, the second structure may include a first sublayer 2021, a second sublayer 2022, a third sublayer 2023, and a fourth sublayer 2024 sequentially stacked on a base substrate. The thickness of the third sublayer is greater than the thickness of any one of the first sublayer, the second sublayer, and the fourth sublayer.

An orthographic projection of a surface of the first sublayer 2021 away from the base substrate 10 on the base substrate 10 covers an orthographic projection of the second sublayer 2022 on the base substrate 10, an orthographic projection of a surface of the second sublayer 2022 away from the base substrate 10 on the base substrate 10 covers an orthographic projection of the third sublayer 2023 on the base substrate 10, and an orthographic projection of a surface of the third sublayer 2023 away from the base substrate 10 on the base substrate 10 covers an orthographic projection of the fourth sublayer 2024 on the base substrate 10. That is, a cross-sectional area of the first sublayer 2021 is greater than a cross-sectional area of the second sublayer 2022, the cross-sectional area of the second sublayer 2022 is greater than a cross-sectional area of the third sublayer 2023, and the cross-sectional area of the third sublayer 2023 is greater than a cross-sectional area of the fourth sublayer 2024.

In an exemplary embodiment of the present disclosure, the conductivity of the third sublayer 2023 is greater than the conductivity of any one of the first sublayer 2021, the second sublayer 2022, and the fourth sublayer 2024.

In an exemplary embodiment of the present disclosure, a preparation material of the first sublayer 2021 includes titanium (Ti), a preparation material of the second sublayer 2022 includes titanium nitride (TiN), a preparation material of the third sublayer 2023 includes aluminum (Al), and a preparation material of the fourth sublayer 2024 includes titanium nitride (TIN).

Metal titanium (Ti), titanium nitride (TiN), aluminum (Al), and titanium nitride Til may be plated sequentially from bottom to top on the anode of the base substrate. In the second structure, TiN is plated on Al, and the two film layers of ITO of the first structure and TiN can protect plated Al from getting yellow, and avoid the damage of etching plasma and cleaning liquid to Al. Plated TiN on top of Al may prevent the relatively active Al from directly contacting ITO, as this could cause Al to take away oxygen element from ITO, leading to indium precipitation and affecting the injection effect of ITO during evaporation.

In an exemplary embodiment of the present disclosure, as shown in FIG. 1, the pixel definition layer may include: a first inorganic layer 301, a second inorganic layer 302, a third inorganic layer 303, and a fourth inorganic layer 304 sequentially stacked on a base substrate.

A surface of the first inorganic layer 301 away from the base substrate 10 is flat, and a distance between the surface of the first inorganic layer 301 away from the base substrate 10 and the base substrate 10 is equal to a distance between a surface of the first structure 201, located in the second electrode region R2 and located on the second structure 202, and the base substrate 10.

In an exemplary embodiment of the present disclosure, as shown in FIG. 1, an orthographic projection of a surface of the first inorganic layer 301 close to the base substrate 10 on the base substrate 10 at least partially overlaps with an orthographic projection of a surface of the first structure 201 on the base substrate 10 on the base substrate 10.

In an exemplary embodiment of the present disclosure, as shown in FIG. 1, an orthographic projection of the second inorganic layer 302 on the base substrate 10 covers an orthographic projection of the first inorganic layer 301 on the base substrate 10, and the second inorganic layer 302 is provided with a first via V1 that exposes the first electrode 20 located in the first electrode region R1.

In an exemplary embodiment of the present disclosure, as shown in FIG. 1, an orthographic projection of the third inorganic layer 303 on the base substrate 10 at least partially overlaps with an orthographic projection of any one of the first inorganic layer 301 and the second inorganic layer 302 on the base substrate 10. The third inorganic layer 303 is provided with a second via V2 and a third via V3, the second via V2 exposes the first electrode 20 located in the first electrode region R1, and the third via V3 exposes the second inorganic layer 302; and the orthographic projection of the first via V1 on the base substrate 10 coincides with the orthographic projection of the second via V2 on the base substrate 10.

In an exemplary embodiment of the present disclosure, as shown in FIG. 1, an orthographic projection of the fourth inorganic layer 304 on the base substrate 10 at least partially overlaps with an orthographic projection of any one of the first inorganic layer 301 and the third inorganic layer 303 on the base substrate 10. The fourth inorganic layer 304 is provided with a fourth via V4 and a fifth via V5, the fourth via V4 exposes the first electrode 20 located in the first electrode region R1, and the fifth via V5 exposes the second inorganic layer 302; and the orthographic projection of the fourth via V4 on the base substrate 10 coincides with the orthographic projection of the second via V2 on the base substrate 10, and the orthographic projection of the fifth via V5 on the base substrate 10 partially overlaps with the orthographic projection of the third via V3 on the base substrate 10.

In an exemplary embodiment of the present disclosure, as shown in FIG. 1, the third via V3 and the fourth via V4 constitute a groove D formed on the pixel definition layer, and the groove D is an undercut structure, so that the light emitting structure layer may be broken at the groove, transmission of the transverse leakage current may be prevented, and reliability of the display substrate can be improved.

In an exemplary embodiment of the present disclosure, as shown in FIG. 1, the thickness of the first inorganic layer 301 is greater than the thickness of any one of the second inorganic layer 302, the third inorganic layer 303, and the fourth inorganic layer 304, and the thickness of the third inorganic layer 303 is greater than the thickness of any one of the second inorganic layer 302 and the fourth inorganic layer 304; and the etching rate of the third inorganic layer 303 is greater than the etching rate of the fourth inorganic layer.

In an exemplary embodiment of the present disclosure, as shown in FIG. 1, a preparation material of the first inorganic layer 301 may include silicon oxide (SiO), a preparation material of the second inorganic layer 302 may include silicon oxide (SiO), a preparation material of the third inorganic layer 303 may include silicon nitride (SiN), and a preparation material of the fourth inorganic layer 304 may include silicon oxide (SiO).

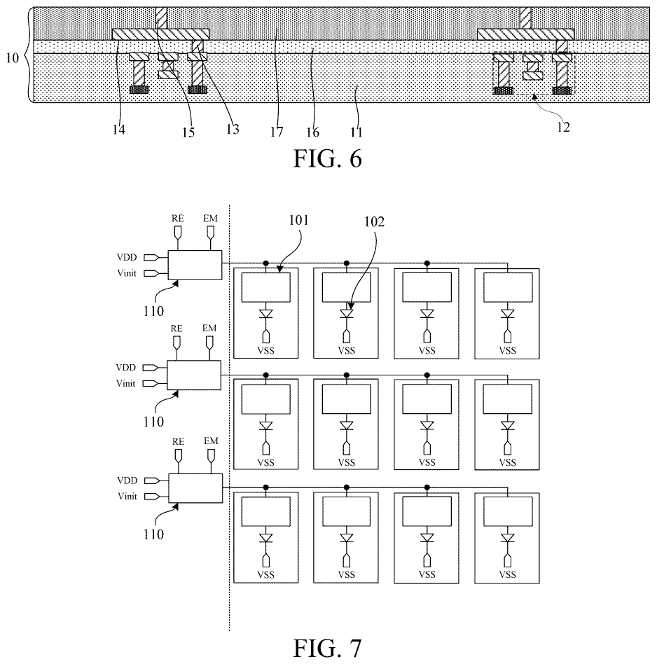

FIG. 6 is a schematic diagram of a structure of a base substrate provided by an embodiment of the present disclosure. As shown in FIG. 6, the base substrate 10 may include: a substrate 11, a transistor 12 disposed in the substrate 11, and a first conductive post 13, a connection electrode 14, and a second conductive post 15 sequentially disposed on the substrate 11. The first conductive post 13 is electrically connected to the transistor 12 and the connection electrode 14, respectively, and the second conductive post 15 is electrically connected to the connection electrode 14 and the first electrode 30, respectively.

In an exemplary implementation, as shown in FIG. 6, the base substrate 10 may further include: a first insulating layer 16 located between the substrate 11 and the connection electrode 14, and a second insulating layer 17 located between the connection electrode 14 and the first electrode 30.

In an exemplary implementation, as shown in FIG. 6, the first insulating layer 16 is provided with a via that exposes the transistor 12, and the first conductive post 13 is located within the via of the first insulating layer.

In an exemplary implementation, as shown in FIG. 6, the second insulating layer 17 is provided with a via that exposes the connection electrode 14, and the second conductive post 15 is located within the via of the second insulating layer.

In an exemplary implementation, an active layer of the transistor 12 is disposed inside the substrate 11.

In an exemplary implementation, the transistor 12 may be a Metal Oxide Semiconductor (MOS).

In an exemplary implementation, the transistor may include: an active layer, a gate electrode, a source electrode, a drain electrode and a gate connection electrode. Herein, the source electrode and the drain electrode are respectively connected to the active layer, and the gate connection electrode is connected to the gate electrode. The transistor may be in a bottom gate structure or may be in a top gate structure.

In an exemplary implementation, a preparation material of the active layer may include: a metal oxide.

In an exemplary implementation, a preparation material of the first insulating layer 16 and the second insulating layer 17 includes at least one of an organic material or an inorganic material, which may be, for example, silicon oxide (SiOx), silicon nitride (SiNx), or silicon oxide nitride (SiON). A structure of the first insulating layer 16 and the second insulating layer 17 may be a single-layer structure or a multi-layer composite structure.

In an exemplary implementation, a preparation material of the first conductive post 13 and the second conductive post 15 may be tungsten.

In an exemplary implementation, a preparation material of the connection electrode 14 includes a metal, for example, which may be silver or aluminum. A structure of the connecting electrode 14 may be a single-layer structure or a multi-layer composite structure.

In an exemplary implementation, the display substrate may include a pixel driving circuit, and the pixel driving circuit includes a plurality of transistors 12 located on the substrate 11, and the transistors may include at least one of a switching transistor, a driving transistor, a reset transistor, and a compensation transistor.

FIG. 7 is a schematic diagram of a circuit principle according to an exemplary implementation. As shown in FIG. 7, multiple sub-pixels in the display region are regularly arranged to form multiple display rows and multiple display columns. Each sub-pixel includes a pixel driving circuit 101, and a light emitting device 102 connected with the pixel driving circuit 101. The pixel driving circuit 101 at least includes a driving transistor. The control circuit at least includes a plurality of voltage control circuits 110, each of which is connected with multiple pixel driving circuits 101. For example, one voltage control circuit 110 is connected with pixel driving circuits 101 in one display row, first electrodes of driving transistors in the pixel driving circuits 101 of the display row are jointly connected to the voltage control circuit 110, a second electrode of each driving transistor is connected with an anode of the light emitting device 102 of the present sub-pixel, and a cathode of the light emitting device 102 is connected to an input end of a second power supply signal VSS. The voltage control circuit 110 is connected with an input end of a first power supply signal VDD, an input end of an initialization signal Vinit, an input end of a reset control signal RE, and an input end of a light emitting control signal EM, respectively. The voltage control circuit 110 is configured to output the initialization signal Vinit to the first electrode of the driving transistor in response to the reset control signal RE, to control the corresponding light emitting device 102 to reset. The voltage control circuit 110 is further configured to, in response to the light emission control signal EM, output the first power supply signal VDD to the first electrode of the driving transistor to drive the light emitting device 102 to emit light. By jointly connecting, by pixel driving circuits 101 in one display row to the voltage control circuit 110, the structure of the pixel driving circuit 101 can be simplified, and an occupied area of the pixel driving circuit 101 can be reduced, so that more pixel driving circuits 101 and light emitting devices 102 are disposed on the display substrate to realize high PPI display. The voltage control circuit 110 outputs the initialization signal Vinit to the first electrode of the driving transistor under the control of the reset control signal RE so as to control the corresponding light emitting device 102 to reset, which can avoid the influence of the voltage applied to the light emitting device 102 during the previous light emission on the next light emission, and can improve the image retention phenomenon.

In an exemplary implementation, one voltage control circuit 110 may be connected to pixel driving circuits 101 in two adjacent sub-pixels in a same display row, or may be connected to pixel driving circuits 101 in three or more sub-pixels in a same display row.

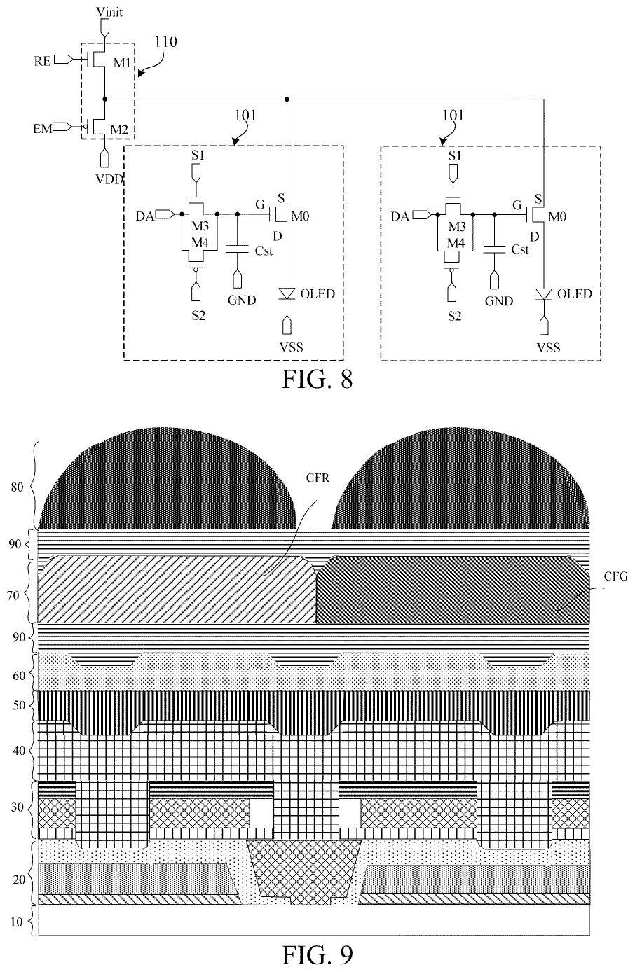

FIG. 8 is a schematic diagram of an implementation of a circuit of a voltage control circuit and a pixel driving circuit. As shown in FIG. 8, the light emitting device may include an OLED. An anode of the OLED is connected with a second electrode D of a driving transistor M0, and a cathode of the OLED is connected with the input end of the second power supply signal VSS.

In an exemplary implementation, a voltage of the second power supply signal VSS may be a negative voltage or a ground voltage V_{GND} (generally 0V). Voltage of the initialization signal Vinit may be the ground voltage V_{GND}.

In an exemplary implementation, the OLED may be a Micro-OLED or a Mini-OLED to facilitate realization of high PPI display.

In an exemplary implementation, the voltage control circuit 110 is connected with two pixel driving circuits 101 in a display row. The pixel driving circuit 101 includes a driving transistor M0, a third transistor M3, a fourth transistor M4 and a storage capacitor Cst, and the voltage control circuit 110 includes a first transistor M1 and a second transistor M2. The driving transistor M0, the first transistor M1, the second transistor M2, the third transistor M3 and the fourth transistor M4 are all transistors fabricated in the substrate.

As shown in FIG. 8, a control electrode of the first transistor M1 is connected to an input end of the reset control signal RE, and is configured to receive the reset control signal RE, a first electrode of the first transistor M1 is connected to an input end of the initialization signal Vinit and is configured to receive the initialization signal Vinit, and a second electrode of the first transistor M1 is connected to a first electrode S of the corresponding driving transistor M0 and a second electrode of the second transistor M2, respectively. A control electrode of the second transistor M2 is connected to the input end of the light emitting control signal EM and is configured to receive a light emitting control signal EM, a first electrode of the second transistor M2 is connected to the input end of the first power source signal VDD and is configured to receive a first power source signal VDD, and the second electrode of the second transistor M2 is connected to the first electrode S of the corresponding driving transistor M0 and the second electrode of the first transistor M1. In an exemplary implementation, the types of the first transistor M1 and the second transistor M2 may be different. For example, the first transistor M1 is an N-type transistor and the second transistor M2 is a P-type transistor, or the first transistor M1 is a P-type transistor and the second transistor M2 is an N-type transistor. In some possible implementations, the types of the first transistor M1 and the second transistor M2 may be same, which may be designed and determined according to an actual application environment.

As shown in FIG. 8, the pixel driving circuit 101 includes: a driving transistor M0, a third transistor M3, a fourth transistor M4, and a storage capacitor Cst. A control electrode G of the driving transistor M0 and the first electrode S of the driving transistor M0 are connected with the second electrode of the first transistor M1 and the second electrode of the second transistor M2, and a second electrode D of the driving transistor M0 is connected with the anode of the OLED. A control electrode of the third transistor M3 is connected to an input end of a first control electrode scan signal S1 and is configured to receive a first control electrode scan signal S1, a first electrode of the third transistor M3 is connected to an input end of a data signal DA and is configured to receive a data signal DA, and a second electrode of the third transistor M3 is connected to the control electrode G of the driving transistor M0. A control electrode of the fourth transistor M4 is connected to an input end of a second control electrode scan signal S2 and is configured to receive a second control electrode scan signal S2, a first electrode of the fourth transistor M4 is connected to the input end of the data signal DA and is configured to receive a data signal DA, and a second electrode of the fourth transistor M4 is connected to the control electrode G of the driving transistor M0. A first terminal of the storage capacitor Cst is connected with the control electrode G of the driving transistor M0, and a second terminal of the storage capacitor Cst is connected with the ground terminal GND. In an exemplary implementation, the driving transistor M0 may be an N-type transistor, and the type of the third transistor M3 may be different from that of the fourth transistor M4, for example, the third transistor M3 is an N-type transistor and the fourth transistor M4 is a P-type transistor. When the voltage of the data signal DA is a voltage corresponding to a high gray scale, by turning on the P-type fourth transistor M4 to transmit the data signal DA to the control electrode G of the driving transistor M0, the voltage of the data signal DA can be prevented from being affected, for example, by the threshold voltage of the N-type third transistor M3. When the voltage of the data signal DA is a voltage corresponding to a low gray scale, by turning on the N-type third transistor M3 to transmit the data signal DA to the control electrode G of the driving transistor M0, the voltage of the data signal DA can be prevented from being affected by the threshold voltage of the P-type fourth transistor M4. In this way, the voltage range input to the control electrode G of the driving transistor M0 can be increased.

In an exemplary implementation, the third transistor M3 is a P-type transistor, and the fourth transistor M4 is an N-type transistor.

In an exemplary implementation, the pixel driving circuit may be a 3T1C, 5T1C or 7T1C circuit structure, or may be a circuit structure with an internal compensation or external compensation function.

FIG. 9 is a schematic diagram of a structure of a display substrate according to another exemplary embodiment of the present disclosure. As shown in FIG. 9, the display substrate may further include: an organic light emitting layer 40, a second electrode 50, an encapsulation layer 60, a filter layer 70, and an optical device layer 80 sequentially stacked on a pixel definition layer. The filter layer includes a plurality of filters. The optical device layer includes a plurality of optical devices. Orthographic projections of adjacent filters on the base substrate are at least partially overlapped, and the plurality of filters correspond in a one-to-one mode with the plurality of optical devices.

An orthographic projection of the filter on the base substrate partially overlaps with an orthographic projection of the corresponding optical device on the base substrate; and there are intervals between adjacent optical devices.

In an example embodiment of the present disclosure, as shown in FIG. 9, the filter layer 70 may include a red filter (CFR) and a green filter (CFG). The optical device layer may have optical devices one-to-one corresponding to the red filter (CFR) and the green filter (CFG).

In an example embodiment of the present disclosure, as shown in FIG. 9, the display substrate may further include an adhesive layer (CT) 90.

In an exemplary embodiment, the interval between adjacent optical devices is smaller than a length of the optical device in the direction perpendicular to the base substrate, and is 0.2 microns to 0.4 microns.

In an exemplary embodiment, a length of the optical device in the direction perpendicular to the base substrate is smaller than a length of the optical device in an extending direction of the base substrate.

In an exemplary embodiment, a length of the optical device in the direction perpendicular to the base substrate is 1 micron to 2 microns, and the length of the optical device in the extending direction of the base substrate is 2 microns to 4 microns.

In an exemplary embodiment, the optical device is a lens.

In an exemplary embodiment, a preparation material of the lens may be a photoresist material.

In an exemplary embodiment, the lens may be hemispherical, or may have other shapes that can converge light.

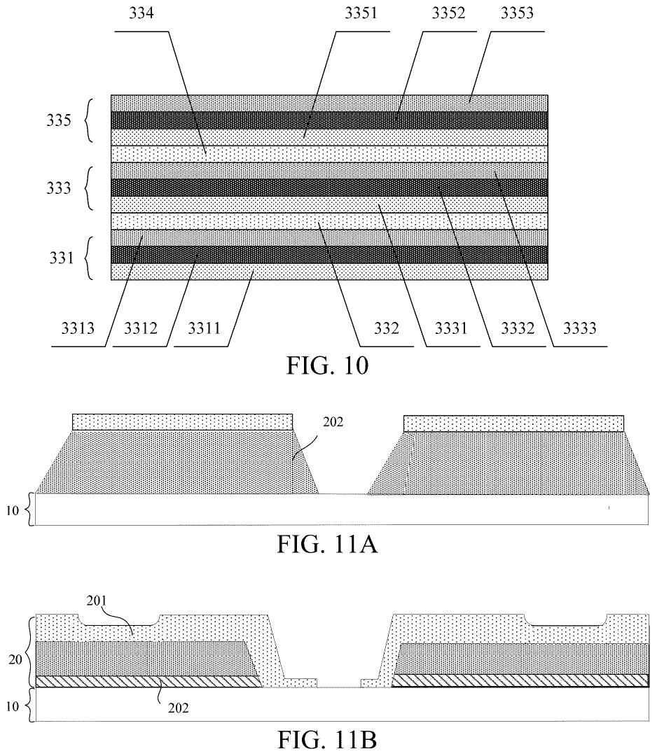

FIG. 10 is a schematic diagram of a structure of an organic light emitting layer according to an embodiment of the present disclosure. As shown in FIG. 10, the organic light emitting layer according to an exemplary embodiment includes a first light emitting sublayer 331, a first charge generating layer 332, a second light emitting sublayer 333, a second charge generating layer 334 and a third light emitting sublayer 335 that are sequentially stacked between the first electrode and the second electrode.

As shown in FIG. 10, the first light emitting sublayer 331 is configured to emit light of a first color, and includes a first hole transporting layer (HTL) 3311, a first emitting material layer (EML) 3312, and a first electron transporting layer (ETL) 3313 which are sequentially stacked. The second light emitting sublayer 333 is configured to emit light of a second color, and includes a second hole transporting layer 3331, a second light emitting material layer 3332 and a second electron transporting layer 3333 which are sequentially stacked. The third light emitting sublayer 335 is configured to emit light of a third color, and includes a third hole transporting layer 3351, a third light emitting material layer 3352 and a third electron transporting layer 3353 which are sequentially stacked. The first charge generating layer 332 is disposed between the first light emitting sublayer 331 and the second light emitting sublayer 333, and is configured to connect the two light emitting sub-layers in series to achieve carrier transfer. The second charge generating layer 334 is disposed between the second light emitting sublayer 333 and the third light emitting sublayer 335, and is configured to connect the two light emitting sub-layers in series to achieve carrier transfer. Since the organic light emitting layer includes a first emitting material layer emitting light of a first color, a second emitting material layer emitting light of a second color and a third light emitting material layer emitting light of a third color, thus light eventually emitted by the organic light emitting layer is mixed light. For example, it may be disposed that the first emitting material layer is a red light material layer emitting red light, the second emitting material layer is a green light material layer emitting green light, and the third emitting material layer is a blue light material layer emitting blue light, and thus the organic light emitting layer eventually emits white light.

In practice, the structure of the organic light emitting layer may be designed according to an actual need. In each light emitting sublayer, in order to improve efficiency of injecting electrons and holes into the light emitting material layer, a hole injection layer and an electron injection layer may also be disposed. In order to simplify the structure of the organic light emitting layer, the first electron transporting layer 3313, the first charge generating layer 332 and the second hole transporting layer 3331 may be removed, that is, the second light emitting material layer 3332 may be disposed directly on the first light emitting material layer 3312.

In an exemplary implementation, the organic light emitting layer may adopt an organic light emitting layer emitting light of a first color and an organic light emitting layer emitting complementary light of the first color, and the two organic light emitting layers are sequentially stacked relative to the base substrate, thereby emitting white light as a whole.

In an exemplary implementation, the second electrode may be a planar electrode.

In an exemplary implementation, the second electrode is a transmission electrode for transmitting light emitted by the organic light emitting layer.

In an exemplary implementation, a preparation material of the second electrode may be indium tin oxide or zinc tin oxide, or another transparent conductive material.

In an exemplary implementation, the display substrate may further include: a color film layer and an encapsulation layer located on a side of the second electrode away from the substrate.

In an exemplary implementation, the encapsulation layer may be a stacked structure and may include: a first inorganic encapsulation layer, a second inorganic encapsulation layer, and an organic encapsulation layer.

In an exemplary implementation, a preparation material of the first inorganic encapsulation layer may include silicon nitride. The first inorganic encapsulation layer may avoid damage to the light emitting structure layer when the second inorganic encapsulation layer is prepared. Since the first inorganic encapsulation layer has an inorganic characteristic, it not only has a good encapsulation characteristic, but also has good adhesion with the second electrode, which ensures encapsulation effect of the encapsulation layer.

In an exemplary implementation, a preparation material of the second inorganic encapsulation layer may include aluminum oxide. The second inorganic encapsulation layer may block water and oxygen from entering the light emitting structure layer, which can prolong the service life of the light emitting structure layer.

In an exemplary implementation, a preparation material of the third organic encapsulation layer may include parylene. Since the third organic encapsulation layer has an organic characteristic, it not only has a better organic encapsulation characteristic, but also has a better particle coating ability, which may well coat particles on a film layer and prevent the film layer from piercing. In addition, a material with an organic characteristic may well release a stress between inorganic layers, and avoid defects such as microcracks or peeling caused by a higher stress. The third organic encapsulation layer 43 also has a better flatness characteristic, which may provide a flatter base substrate for subsequent color filter layer preparation and prevent the color filter layer preparation process from damaging the second inorganic encapsulation layer. In an exemplary implementation, the first inorganic encapsulation layer and the second inorganic encapsulation layer are formed using a deposition process; and a deposition density of the first inorganic encapsulation layer is smaller than a deposition density of the second inorganic encapsulation layer.

In an exemplary implementation, the display substrate may further include a cover plate. The cover plate is located on a side of the optical device layer away from the base substrate.

In an exemplary implementation, the display substrate further includes a frame sealant. The cover plate is fixed with the base substrate through the frame sealant. Herein, the frame sealant is arranged between the base substrate and the cover plate, which can provide protection for blocking the invasion of water and oxygen, and greatly improve the service life of a silicon-based OLED display substrate. In another exemplary implementation, the frame sealant may be disposed on a side of the cover plate, peripheral sides of the cover plate and the base substrate are sealed by the frame sealant, and an end face on a side of the frame sealant away from the base substrate is located between a surface of the cover plate adjacent to the base substrate and a surface of the cover plate away from the base substrate. This arrangement both may ensure the sealing effect and may prevent the frame sealant from protruding above the cover plate, thereby avoiding an increase in the thickness of the display substrate.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition. The coating may be any one or more of spray coating, spin coating, and inkjet printing. A “thin film” refers to a layer of thin film made of a certain material on a base substrate using deposition, coating, or other processes. If the “thin film” does not need a patterning process in an entire preparation process, the “thin film” may also be called a “layer”. If the “thin film” needs a patterning process throughout the whole preparation process, it is referred to as a “thin film” before the patterning process and as a “layer” after the patterning process. The “layer” after the patterning process includes at least one “pattern”. “A and B are arranged in the same layer” mentioned in the present disclosure refers to that A and B are simultaneously formed by the same patterning process. The “thickness” of the thin film layer is a size of the film layer in a direction perpendicular to the display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

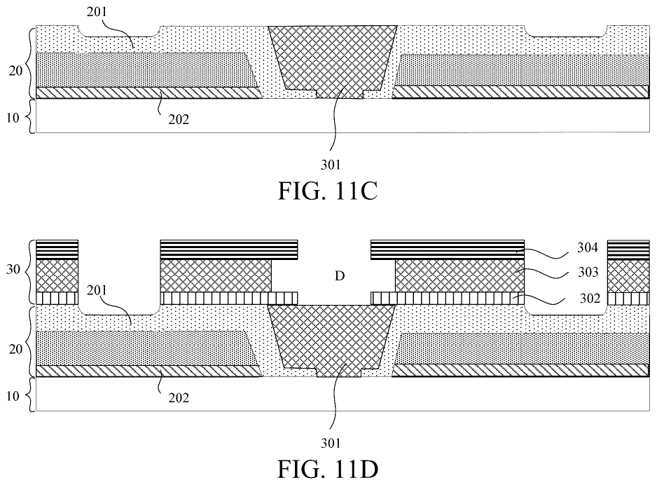

In an exemplary implementation of the present disclosure, taking the display substrate provided in FIG. 1 as an example, the preparation process of the display substrate may include the following operations.
(1) A second structure of a first electrode is formed: FIG. 11A is a first schematic diagram of a display substrate according to an embodiment of the present disclosure. As shown in FIG. 11A, a first metal film, a second metal film, a third metal film, and a fourth metal film are deposited on a base substrate 10, and the first metal film, the second metal film, the third metal film, and the fourth metal film are patterned by a patterning process to form a second structure 202.

In an exemplary implementation, the first metal film, the second metal film, the third metal film, and the fourth metal film may be titanium (Ti), titanium nitride (TiN), aluminum (Al), titanium nitride TiN, and indium TiN oxide (ITO), respectively, that is, titanium (Ti), titanium nitride (TiN), aluminum (Al), titanium nitride TiN, and indium TiN oxide (ITO) may be plated sequentially from bottom to top on an anode on a CMOS substrate.

In an exemplary implementation, TiN and ITO may be plated over Al, and thicknesses of TiN and ITO are very thin, and the two film layers of TiN and ITO may protect plated Al from getting yellow, and avoid damage of etching plasma and cleaning liquid to Al. Plating TiN on top of Al may prevent the relatively active Al from directly contacting ITO, as this could cause Al to take away oxygen element from ITO, leading to the indium precipitation and affecting the injection effect of ITO during evaporation.
(2) A first structure of the first electrode is formed: FIG. 11B is a second schematic diagram of an organic light-emitting diode display substrate according to an embodiment of the present disclosure. As shown in FIG. 11B, a transparent metal thin film is deposited on the second structure obtained in FIG. 11A, the transparent metal thin film is patterned by a patterning process to form a first structure 201, and a first electrode 20 including the first structure 201 and the second structure 202 is formed.

In an exemplary implementation, the transparent metal thin film may be indium tin oxide (ITO), and coating the metal sidewall of the anode with ITO may protect Al and avoid corrosion of Al at a pixel sidewall in a subsequent preparation process. In addition, Al at the pixel sidewall directly contacts ITO, and even if there is an indium precipitation caused by the oxygen element of ITO taken away by Al, a light emission effect will not be affected because this region is not a light emitting region.
(3) A first inorganic layer of a pixel definition layer is formed. FIG. 11C is a third schematic diagram of an organic light-emitting diode display substrate according to an embodiment of the present disclosure. As shown in FIG. 11C, a first inorganic thin film is deposited on the first electrode 20 obtained in FIG. 11B, and the first inorganic layer 301 is formed by two patterning processes. The first inorganic thin film may be silicon oxide (SiO).

In an exemplary implementation, the present disclosure may deposit silicon oxide using a Plasma Enhanced Chemical Vapor Deposition (PECVD) process.

In an exemplary implementation, the etching may be carried out in two steps: in the first step, the photoresist on the entire surface is etched, and the second step is performed after the photoresist (PR) above the pixel is etched. In the second step, the selection ratio of photoresist to SiO is controlled to 1:1, and ITO above the pixel is exposed after simultaneously thinning the photoresist and SiO.
(4) A second inorganic layer 302, a third inorganic layer 303, and a fourth inorganic layer 304 of the pixel definition layer are formed: FIG. 11D is a fourth schematic diagram of an organic light-emitting diode display substrate according to an embodiment of the present disclosure. As shown in FIG. 11D, a second inorganic thin film, a third inorganic thin film, and a fourth inorganic thin film are deposited on the first inorganic layer 301 obtained in FIG. 11C, and the second inorganic thin film, the third inorganic thin film, and the fourth inorganic thin film are patterned to form the second inorganic layer 302, the third inorganic layer 303, and the fourth inorganic layer 304 by a patterning process. And a pixel definition layer 30 including the first inorganic layer 301, the second inorganic layer 302, the third inorganic layer 303, and the fourth inorganic layer 304 is formed.

In an exemplary implementation, a groove D is provided on the pixel definition layer.

In an exemplary implementation, the second inorganic thin film, the third inorganic thin film, and the fourth inorganic thin film may be plated with silicon oxide (SiO), silicon nitride (SiN), and silicon oxide (SiO), respectively.

In an exemplary implementation, the selection ratio for etching the second inorganic thin film to the transparent metal thin film is about 20:1 to 40:1; and the selection ratio for the etching the fourth inorganic thin film to the third inorganic thin film is about 1:6 to 1:9.

In an exemplary implementation, in the present disclosure, the first inorganic layer 301 may be sequentially plated with silicon oxide (SiO), silicon nitride (SiN), and silicon oxide (SiO) using a plasma chemical vapor deposition process (PECVD), photoresist is coated, exposure and development processings are performed, and dry etching is performed to open a PDL opening. During the etching process of PDL, the selection ratio of SiO to ITO on a lower layer is controlled between 20:1 and 40:1, and an over-etching amount is controlled, so that an ITO thickness at the non-opening of PDL is 1.3 to 4 times of an ITO thickness at the PDL opening.

In an exemplary implementation, a groove D in the pixel definition layer is formed due to the etching selection ratio difference between SiO and SiN, and the groove is an undercut structure.

In an exemplary implementation, sulfur hexafluoride (SF6) may be used for etching, and the selection ratio of SiO to SiN is controlled to range from 1:6 to 1:9.

Embodiments of the present disclosure also provide a method for preparing a display substrate, configured to prepare a display substrate. The method for preparing a display substrate may include the following acts 100 and 200.

In act 100, a first electrode is formed on a base substrate.

In an exemplary implementation, the sidewall of the first electrode is stepped.

In act 200, a pixel definition layer is formed on the first electrode.

In an exemplary implementation, the pixel definition layer is provided with a pixel opening that exposes the first electrode, a region in which the first electrode is located includes a first electrode region and a second electrode region. An orthographic projection of a first electrode located in the first electrode region on the base substrate coincides with an orthographic projection of the pixel opening on the base substrate, and an orthographic projection of a first electrode located in the second electrode region on the base substrate partially overlaps with an orthographic projection of the pixel definition layer on the base substrate; and a thickness of the first electrode located in the first electrode region is smaller than a thickness of the first electrode located in the second electrode region.

The display substrate is the display substrate according to any of the aforementioned embodiments, and has similar implementation principles and implementation effects, which will not be repeated here.

In an exemplary embodiment of the present disclosure, forming the first electrode on the base substrate may include: depositing a first metal film, a second metal film, a third metal film, and a fourth metal film on a base substrate; and patterning the first metal film, the second metal film, the third metal film, and the fourth metal film by a patterning process to form a second structure; and depositing a transparent metal thin film on the second structure, patterning the transparent metal thin film by a patterning process to form a first structure, and forming a first electrode including the first structure and the second structure.

In an example embodiment of the present disclosure, forming the pixel definition layer on the first electrode may include: depositing a first inorganic thin film on the first electrode, and forming a first inorganic layer by two patterning processes; depositing a second inorganic thin film, a third inorganic thin film, and a fourth inorganic thin film on the first inorganic layer; patterning the second inorganic thin film, the third inorganic thin film, and the fourth inorganic thin film by a patterning process to form a second inorganic layer, a third inorganic layer, and a fourth inorganic layer; and forming the pixel definition layer including the first inorganic layer, the second inorganic layer, the third inorganic layer, and the fourth inorganic layer.

A selection ratio for etching the second inorganic thin film to the transparent metal thin film is about 20:1 to 40:1; and a selection ratio for etching the fourth inorganic thin film to the third inorganic thin film is about 1:6 to 1:9.

An embodiment of the present disclosure further provides a display apparatus including a display substrate.

The display substrate is the display substrate according to any of the aforementioned embodiments, and has similar implementation principles and implementation effects, which will not be repeated here.

In an exemplary implementation, the display apparatus includes a VR device or an AR device.

In an exemplary implementation, the display apparatus may be any product or component with a display function, such as a mobile phone, a tablet computer, a television, a display, a laptop computer, a digital photo frame, or a navigator, and the embodiments of the present disclosure do not impose any limitations thereto.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations used for ease of understanding of the present disclosure, but not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A display substrate, comprising: a base substrate, and a first electrode and a pixel definition layer sequentially arranged on the base substrate; wherein the pixel definition layer is provided with a pixel opening exposing the first electrode; a region in which the first electrode is located comprises: a first electrode region, a second electrode region and a smooth transition region; wherein the smooth transition region is located between the first electrode region and the second electrode region, an orthographic projection of a first electrode located in the first electrode region on the base substrate coincides with an orthographic projection of the pixel opening on the base substrate, and an orthographic projection of a first electrode located in the second electrode region on the base substrate partially overlaps with an orthographic projection of the pixel definition layer on the base substrate;
a thickness of the first electrode located in the first electrode region is smaller than a thickness of the first electrode located in the second electrode region.

2. The display substrate of claim 1, wherein an orthographic projection of an edge of a top layer of the pixel definition layer on the base substrate is located within an orthographic projection of the smooth transition region on the base substrate.

3. The display substrate of claim 1, wherein the first electrode comprises a first structure and a second structure, and the first structure is located on a side of the second structure away from the base substrate;
an orthographic projection of the first structure on the base substrate covers an orthographic projection of the second structure on the base substrate, and a thickness of the second structure is greater than a thickness of the first structure;
the first structure covers a side wall of the second structure.

4. The display substrate of claim 3, wherein a surface of the second structure close to the pixel definition layer is flat;
a first thickness is a thickness of a first structure located in the first electrode region, and a second thickness is a thickness of a first structure located in the second electrode region, and the first thickness is less than the second thickness.

5. The display substrate of claim 4, wherein a ratio of the second thickness to the first thickness ranges from 1.3/1 to 4/1.

6. The display substrate of claim 4, wherein a third thickness is a thickness of a pixel definition layer of which an orthographic projection on the base substrate overlaps with an orthographic projection of a surface of the second structure close to the pixel definition layer on the base substrate;
a ratio of the third thickness to a thickness difference is in the range of 10:1 to 20:1, wherein the thickness difference is a difference between the second thickness and the first thickness.

7. The display substrate of claim 3, wherein the first structure is a transparent electrode structure, and a thickness of the first structure is greater than 80 angstroms.

8. The display substrate of claim 3, wherein the second structure comprises: a first sublayer, a second sublayer, a third sublayer, and a fourth sublayer sequentially stacked on the base substrate; wherein a thickness of the third sublayer is greater a thickness of any one of the first sublayer, the second sublayer, and the fourth sublayer;
an orthographic projection of a surface of the first sublayer away from the base substrate on the base substrate covers an orthographic projection of the second sublayer on the base substrate, and an orthographic projection of a surface of the second sublayer away from the base substrate on the base substrate covers an orthographic projection of the third sublayer on the base substrate, and an orthographic projection of a surface of the third sublayer away from the base substrate on the base substrate covers an orthographic projection of the fourth sublayer on the base substrate;
a side wall of the second structure is inclined.

9. The display substrate of claim 8, wherein a conductivity of the third sublayer is greater than a conductivity of any one of the first sublayer, the second sublayer, and the fourth sublayer.

10. The display substrate of claim 9, wherein a preparation material of the first sublayer comprises titanium, a preparation material of the second sublayer comprises titanium nitride, a preparation material of the third sublayer comprises aluminum, and a preparation material of the fourth sublayer comprises titanium nitride.

11. The display substrate of claim 3, wherein the pixel definition layer comprises: a first inorganic layer, a second inorganic layer, a third inorganic layer, and a fourth inorganic layer sequentially stacked on the base substrate;
a surface of the first inorganic layer away from the base substrate is flat, and a distance between the surface of the first inorganic layer away from the base substrate and the base substrate is equal to a distance between a surface of a first structure located in the second electrode region and located on the second structure and the base substrate.

12. The display substrate of claim 11, wherein an orthographic projection of a surface of the first inorganic layer close to the base substrate on the base substrate at least partially overlaps with an orthographic projection of a surface of the first structure on the base substrate on the base substrate.

13. The display substrate of claim 11, wherein an orthogonal projection of the second inorganic layer on the base substrate covers an orthogonal projection of the first inorganic layer on the base substrate, the second inorganic layer is provided with a first via, and the first via exposes the first electrode located in the first electrode region.

14. The display substrate of claim 13, wherein an orthographic projection of the third inorganic layer on the base substrate at least partially overlaps with an orthographic projection of any one of the first inorganic layer and the second inorganic layer on the base substrate;
the third inorganic layer is provided with a second via and a third via, wherein the second via exposes the first electrode located in the first electrode region, and the third via exposes the second inorganic layer;
an orthographic projection of the first via on the base substrate coincides with an orthographic projection of the second via on the base substrate.

15. The display substrate of claim 14, wherein an orthographic projection of the fourth inorganic layer on the base substrate at least partially overlaps with an orthographic projection of any one of the first inorganic layer and the third inorganic layer on the base substrate;
the fourth inorganic layer is provided with a fourth via and a fifth via, the fourth via exposes the first electrode located in the first electrode region, and the fifth via exposes the second inorganic layer;
an orthogonal projection of the fourth via on the base substrate coincides with the orthogonal projection of the second via on the base substrate, and an orthogonal projection of the fifth via on the base substrate partially overlaps with an orthogonal projection of the third via on the base substrate.

16. (canceled)

17. The display substrate of claim 11, wherein a thickness of the first inorganic layer is greater than a thickness of any one of the second inorganic layer, the third inorganic layer, and the fourth inorganic layer, and a thickness of the third inorganic layer is greater than a thickness of any one of the second inorganic layer and the fourth inorganic layer;
an etching rate of the third inorganic layer is greater than an etching rate of the fourth inorganic layer.

18. The display substrate of claim 11, wherein a preparation material of the first inorganic layer comprises silicon oxide, a preparation material of the second inorganic layer comprises silicon oxide, a preparation material of the third inorganic layer comprises silicon nitride, and a preparation material of the fourth inorganic layer comprises silicon oxide.

19. (canceled)

20. A display apparatus, comprising: the display substrate of claim 1.

21. A preparation method for a display substrate, configured to prepare the display substrate of claim 1, the method comprising:
forming the first electrode on the base substrate; and
forming the pixel definition layer on the first electrode.

22. The preparation method for a display substrate of claim 21, wherein forming the first electrode on the base substrate comprises: depositing a first metal film, a second metal film, a third metal film, and a fourth metal film on the base substrate; patterning the first metal film, the second metal film, the third metal film, and the fourth metal film by a patterning process to form a second structure; and
depositing a transparent metal thin film on the second structure, patterning the transparent metal thin film by a patterning process to form a first structure, and forming the first electrode including the first structure and the second structure.

23. (canceled)
